(19) United States
(12) Patent Application Publication
(10) Pub. No.: US 2018/0292749 A1
(43) Pub. Date: Oct. 11, 2018

(54) BLUE COLOR-RESIST, COLOR FILM SUBSTRATE, AND LIQUID CRYSTAL DISPLAY

(71) Applicants: BOE TECHNOLOGY GROUP CO., LTD., Beijing (CN); HEFEI XINSHENG OPTOELECTRONICS TECHNOLOGY CO., LTD., Hefei, Anhui (CN)

(72) Inventors: Huifang Yuan, Beijing (CN); Sang Man Yuk, Beijing (CN); Tao Zhu, Beijing (CN); Wenhao Tang, Beijing (CN); Haibin Yin, Beijing (CN); Anxin Dong, Beijing (CN); Guoqiang Zhong, Beijing (CN); Qun Fang, Beijing (CN); Jian Chen, Beijing (CN); Ya Yu, Beijing (CN); Rui Yin, Beijing (CN)

(73) Assignees: BOE TECHNOLOGY GROUP CO., LTD., Beijing (CN); HEFEI XINSHENG OPTOELECTRONICS TECHNOLOGY CO., LTD ., Hefei, Anhui (CN)

(21) Appl. No.: 15/573,932

(22) PCT Filed: May 3, 2017
(86) PCT No.: PCT/CN2017/082830

§ 371 Date: Nov. 14, 2017

(30) Foreign Application Priority Data
Nov. 14, 2016 (CN) 201611023844.3

(51) Int. Cl. G03F 7/00; G03F 7/033; G03F 7/031; G02F 1/1335

(52) U.S. Cl. CPC G03F 7/0007; G02F 1/133514; G03F 7/031; G03F 7/033

(57) ABSTRACT

A blue color-resist for a liquid crystal display. The blue color-resist contains a blue pigment and a green pigment. A wavelength of a blue light after being transmitted through the blue color-resist is shifted toward infrared region.

### CROSS-REFERENCE TO RELATED APPLICATIONS

This application claims the benefit of the filing date of Chinese Patent Application No. 201611023844.3 filed on Nov. 14, 2016, the disclosure of which is hereby incorporated by reference.

### TECHNICAL FIELD

This invention relates to a liquid crystal display technology, and more particularly, to a color-resist, a color film substrate, and a liquid crystal display apparatus, and the application thereof.

### BACKGROUND

Liquid crystal display (LCD) is a display device based on electro-optic effect of liquid crystals. LCD typically includes a liquid crystal display panel and a backlight module. The liquid crystal display panel usually includes a color film substrate and a liquid crystal cell. The color film substrate is usually composed of a transparent substrate, and a black matrix and a color filter layer distributed on the transparent substrate. The color filter layer is usually composed of red color-resist, green color-resist, and blue color-resist, which are arranged to form a plurality of repeated array of color-resist units. The black matrix is used to separate the color-resists. The backlight module emits light which is transmitted through the liquid crystal cell in the liquid crystal display panel and enters the above-mentioned respective color-resist to be filtered into a light of the corresponding color. For example, a white light passing through the red color-resist is filtered into a transmitted red light. Likewise, a white light passing through the green color-resist is filtered into a transmitted green light, and a white light passing thorough the blue color-resist is filtered into a transmitted blue light. The transmitted lights of the above-mentioned colors are mixed in a specific ratio and then incident on human eye to display a desired color.

### BRIEF SUMMARY

Accordingly, one example of the present disclosure is a blue color-resist. The blue color-resist may comprise a blue pigment and a green pigment. A mass ratio of the blue pigment to the green pigment is approximately in a range of 1:1 to 50:1. In another embodiment, a mass ratio of the blue pigment to the green pigment is approximately in a range of 1:1 to 9:1. The blue color-resist may be configured to have an anti-blue light efficiency of about 9% or more. In another embodiment, the blue color-resist may be configured to have an anti-blue light efficiency of about 20% or more.

A wavelength of a blue light after being transmitted through the blue color-resist may be shifted toward infrared region. In one embodiment, a peak wavelength of a blue light after being transmitted through the blue color-resist is red-shifted to a range of 475 nm to 495 nm.

The blue pigment may comprise at least one selected from the group consisting of Pigment Blue 15:6, Pigment Blue 15:4, and Pigment Blue 15:3. The green pigment may comprise at least one selected from the group consisting of Pigment Green 58, Pigment Green 7, Pigment Green 36, and Pigment Green 59. The blue pigment may further comprise pigment violet 23.

Starting raw materials for preparing the blue color-resist may comprise a) a binder resin, b) a monomer, c) a photoinitiator, d) a solvent, and e) a mixture of the blue pigment and the green pigment. A mass ratio of the binder resin:the monomer:the photoinitiator:the solvent:the mixture of the blue pigment and the green pigment may be in a range of 5-8:5-8:0.2-0.6:75-85:5-8, respectively.

The binder resin may comprise an acrylic resin. The monomer may comprise at least one selected from the group consisting of dipentaerythritol hexaacrylate, trimethylolpropane triacrylate, and pentaerythritol triacrylate. The photoinitiator may comprise at least one selected from the group consisting of Photoinitiator 369, Photoinitiator 379, Photoinitiator OXE-1, and Photoinitiator OXE-2. The solvent may comprise at least one selected from the group consisting of ethyl 3-ethoxypropionate, propylene glycol methyl ether, propylene glycol methyl ether acetate, and N, N-methylenebisacrylamide.

Another example of the present disclosure is a color film substrate comprising the blue color-resist according to one embodiment of the present disclosure.

Another example of the present disclosure is a liquid crystal display apparatus comprising the color film substrate according to one embodiment of the present disclosure.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 shows wavelength distribution of transmitted blue lights after passing through blue color-resists having different ratios of a blue pigment to a green pigment according to some embodiments.

FIG. 2 shows a weighted damage of a blue light (a) before passing through a blue color-resist, (b) after passing through a blue color-resist, according to one embodiment.

### DETAILED DESCRIPTION

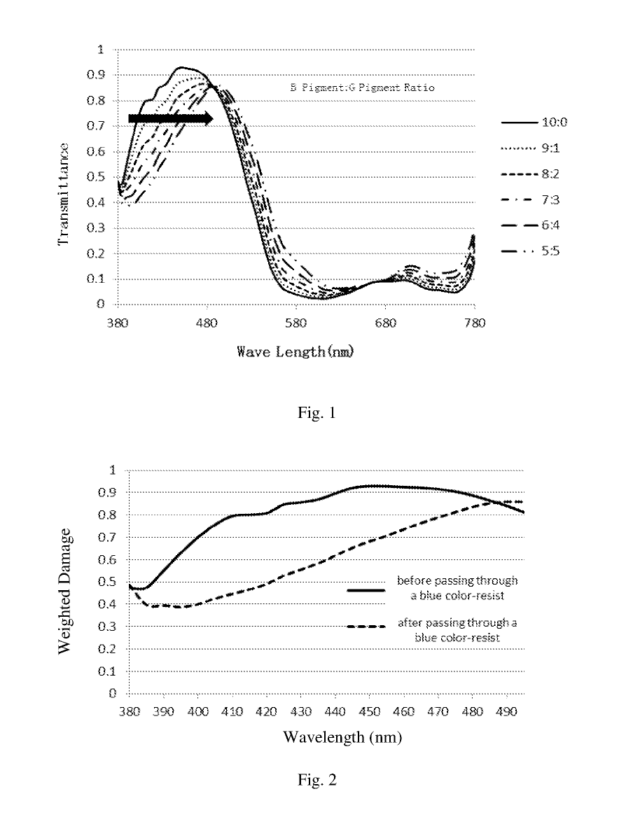

The present invention is described with reference to embodiments of the invention. Throughout the description of the invention reference is made to FIGS. 1 and 2. When referring to the figures, like structures and elements shown throughout are indicated with like reference numerals.

Blue light with a wavelength of 400 nm to 480 nm close to ultraviolet light has high energy. The blue light with the wavelength of 400 nm to 480 nm can penetrate crystalline lens and vitreous body in human eye, directly reach macular area of a retina, damage retina photoreceptor cells, and accelerate macular cell oxidation, thereby causing damage to the human eye. Therefore, in order to protect eyes, it is desirable that light intensity of the blue light after passing through the blue color-resist is weakened or a wavelength thereof is reduced, thereby achieving anti-blue light effect.

Accordingly one example of the present disclosure provides a blue color-resist capable of shifting a wavelength of a transmitted blue light after passing through the blue color-resist toward red light region and its application thereof. After a light passes through the blue color-resist, the spectrum is shifted toward the red region, thereby effectively reducing a blue light damage density. May be use weighted of the blue light. Further, based on the blue color-resist, the present disclosure also provides an anti-blue color film substrate and a liquid crystal display.

In one embodiment, the blue color-resist comprises a blue pigment and a green pigment. In this embodiment, a blue color-resist with anti-blue light function is obtained by adding a green pigment into a blue pigment. After a light passes through the blue color-resist, a wavelength of the transmitted blue light can be shifted toward the infrared region. Accordingly, damage to the human eye by the transmitted blue light can be reduced, thereby achieving anti-blue light effect. In addition, as a ratio of the green pigment to the blue pigment in the blue color-resist increases, the redshift effect of the transmitted blue light after passing through the blue color-resist becomes more obvious. The ratio of the green pigment to the blue pigment in the blue color-resist can be determined according to requirement of hue and redshift effect of the transmitted blue light.

The blue color-resist according to one embodiment of the present disclosure has the following function: a wavelength of the transmitted blue light is shifted in the direction of the infrared region after passing through the blue color-resist. In the embodiment, damage of the transmitted blue light to human eye is reduced by shifting the wavelength of the transmitted blue light after passing through the blue color-resist in the direction of the infrared region. More specifically, when the light passes through the blue color-resist, the peak wavelength of the transmitted blue light is red-shifted to a region of 475 nm to 495 nm. Therefore, although the transmitted blue light is still in the blue light region, the damage to human eye has been significantly weakened because the peak wavelength of the transmitted blue light, which corresponds with the brightest portion of the corresponding transmitted blue light, is red-shifted to a region of 475 nm to 495 nm, thereby achieving a strong anti-blue light effect.

Specifically, a mass ratio of the blue pigment and the green pigment in the blue color-resist is determined according to the required anti-blue light effect of the blue color-resist. The higher the mass ratio of the green pigment to the blue pigment, the better the anti-blue light effect of the blue color-resist. Furthermore, the mass ratio of the blue pigment to the green pigment is also determined according to the required hue of the transmitted blue light after passing through the blue color-resist. The required hue of the transmitted blue light depends on specifications of specific products. In general, the deeper the blue color, the smaller mass ratio of the green pigment added to the blue pigment. The mass ratio of the blue pigment to the green pigment in the blue color-resist may be 1 to 50:1, such as 1-9:1, 1-20:1, 1-30:1, or 1-40:1, etc. and preferably 1-9:1 such as 1:1, 2:1, 3:1, 4:1, 5:1, 6:1, 7:1, 8:1, or 9:1 etc. A blue color-resist can be prepared to satisfy the requirement of both anti-blue light effect and hue, thereby adapting to different sensory effects. If there is no green pigment in a blue-color resist, the peak wavelength of the transmitted blue light after passing through the blue-color resist is measured to be at 470 nm. If an equal amount of a green pigment is added into a blue pigment to form a blue color-resist, the peak wavelength of the transmitted blue light after passing through the blue-color resist is measured to be red-shifted from 470 nm to 495 nm.

Blue pigments used to prepare blue color-resists are not limited and have many different types. In one embodiment, the blue color-resist comprises at least a blue pigment selected from the group consisting of Pigment Blue 15:6, Pigment Blue 15:4, and Pigment Blue 15:3 and a mixture thereof. For example, the blue color pigment may be one of the Pigment Blue 15:6, Pigment Blue 15:4, or Pigment Blue 15:3, or a combination of any two or three thereof. The blue color-resist may comprise at least a green pigment selected from the group consisting of Pigment Green 58 (i.e., C.I. Pigment Green 58), Pigment Green 7, Pigment Green 36, Pigment Green 59, and a mixture thereof. For example, the green pigment may be Pigment Green 58 (i.e., C.I. Pigment Green 58), Pigment Green 7, Pigment Green 36, or Pigment Green 59, or a combination of any two, three, or four thereof.

In one embodiment, the blue pigment also includes Pigment Violet 23. The purpose of adding Pigment Violet 23 is to adjust color of the blue pigment to obtain a desirable red light blue. The mass fraction of the pigment purple 23 in the blue pigment is generally less than 40%, such as 5%, 10%, 15%, 20%, 25%, 30%, 35% or the like.

In one embodiment, in a process of preparing the blue color-resist, particle sizes of both the blue pigment and the green pigment are less than 100 nm. Such particle sizes are advantageous in obtaining a smooth coating film.

Properties of each of the above pigments are summarized below: Pigment Blue 15:6, which is also known as phthalocyanine blue (ε-crystal) and has a molecular formula of C₃₂H₁₆CuN₈, has more pure and bright, red light blue color. Pigment Blue 15:4, which is also known as phthalocyanine blue (anti-crystalline anti-flocculation (β-crystal) and has a molecular formula of C₃₂H₁₆CuN₈, has a pure green blue color with high color strength and good flow properties. Pigment Blue 15:3, which is also known as phthalocyanine blue (stable β-crystal) and has a molecular formula of C₃₂H₁₆CuN₈, has pure, bright green light blue color and stable chemical stability. A detailed description of each of the above blue pigments can also be obtained from the Gade Chemical website.

Pigment Green 7 shows dark green with advantages such as bright color, strong color strength, and so on. The chemical structure of Pigment Green 7 is as follows:

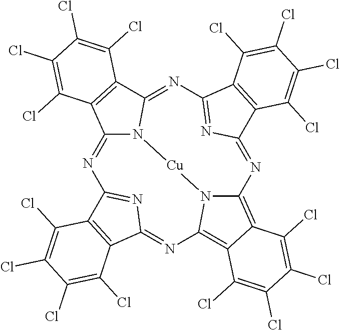

Pigment Green 36, which is also known as phthalocyanine green 36, shows yellow light green color with advantages such as bright color, high color strength, excellent light and heat resistance, insoluble in water and organic solvents, and so on. The chemical structure of Pigment green 36 is as follows:

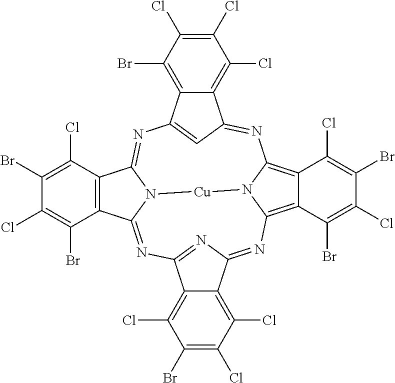

The chemical structure and formation of Pigment Green 59 is described in the Chinese patent application No. 106019837A, entitled “a coloring photosensitive resin composition, a color filter, and an image display device.”

In addition to the above pigments, raw materials used to prepare the blue color-resist may also comprise a binder resin, a monomer, a photoinitiator, a solvent, or optional additives. In one embodiment, in order to obtain a blue color-resist for a color film substrate, raw materials for preparing the blue color-resist comprise at least the following five components: a) a binder resin, b) a monomer, c) a photoinitiator, d) a solvent, and e) a mixture of a blue pigment and a green pigment. The mixture of the blue pigment and the green pigment comprises the blue pigment and the green pigment at a specific ratio. A mass ratio of a) a binder resin, b) a monomer, c) a photoinitiator, d) a solvent, and e) a mixture of a blue pigment and a green pigment is within a range of 5-8:5-8:0.2-0.6:75-85:5-8. In one embodiment, the mass ratio thereof is 6:5:0.3:78:8. In another embodiment, the mass ratio thereof is 8:5:0.2:85:7.

In one embodiment, a binder resin is used as a film-forming substrate of a blue color-resist. The binder resin may include an alkali-soluble resin, such as an acrylic resin, a methacrylic resin, a styrene maleic anhydride resin, or the like. In one embodiment, the binder resin is an alkali-soluble photosensitive acrylic resin. For example, Liu Pengfei, Chen Ning, Liu Ren et al. discloses a synthesis process of an alkali-soluble photosensitive acrylic resin and its application in optical imaging systems in the book entitled “New Chemical Materials” (2010.38 (9): 81-84).

The monomer can be polymerized by an active radical produced by a photoinitiator under light irradiation to produce an oligomer having a weight average molecular weight of preferably 3000 or less. The monomer may include: trimethylolpropane tri(meth)acrylate, pentaerythritol tri(meth)acrylate, pentaerythritol tetra(meth)acrylate, dipentaerythritol penta(meth)acrylate, dipentaerythritol hexa(meth)acrylate, tripentaerythritol octa (meth) acrylate, tripentaerythritol hexa (meth) acrylate, tetrapentaerythritol ten (meth) acrylate, tetrapentaerythritol hexa (meth) acrylate, tris (2-(meth) acryloyloxyethyl)isocyanurate, ethylene glycol modified pentaerythritol tetra(meth)acrylate, ethylene glycol modified dipentaerythritol hexa(meth)acrylate, propylene glycol modified pentaerythritol tetra(meth)acrylate, propylene glycol modified dipentaerythritol hexa(meth)acrylate, caprolactone modified pentaerythritol tetra(meth)acrylate, caprolactone modified dipentaerythritol hexa(methyl)acrylates or the like. Trimethylolpropane tri(meth)acrylate, pentaerythritol tri(meth)acrylate, and dipentaerythritol hexa(meth)acrylate are preferred.

The solvent is mainly used for uniformly dispersing the above components to form a uniform coating film. From the viewpoint of coating property and drying property, the solvent may include: propylene glycol monomethyl ether acetate, dipropylene glycol methyl ether acetate, ethyl lactate, propylene glycol methyl ether, propylene glycol methyl ether acetate, ethyl 3-ethoxypropionate, ethylene glycol monomethyl ether, diethylene glycol monomethyl ether, diethylene glycol monoethyl ether, 3-methoxyacetate, 3-methoxy-1-butanol, 4-hydroxy-4-methyl-2-pentanol, N, N-dimethylformamide, N, N-methylene bisacrylamide or the like. Ethyl 3-ethoxypropionate, propylene glycol methyl ether, and N, N-methylene bisacrylamide are preferred.

The photoinitiator may include Photoinitiator 369, Photoinitiator 379, Photoinitiator OXE-1, or Photoinitiator OXE-2. With regard to Photoinitiator 369, the chemical name is 2-phenylbenzyl-2-dimethylamine-1-(4-morpholinephenyl) butanone, the molecular formula is C₂₃H₃₀N₂O₂, and the CAS No. is 119313-12-1. With regard to Photoinitiator 379, the molecular formula is C₂₄H₃₂N₂O₂, the CAS No. is 119344-86-4, and the molecular structure is as follows:

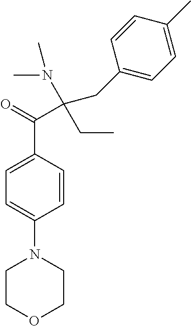 [SMILES: CCC(Cc1ccc(C)cc1)(C(=O)c1ccc(N2CCOCC2)cc1)N(C)C]

In one embodiment, the Photoinitiator 369 and the Photoinitiator 379 are IRGACURE® 369 and IRGACURE® 379, respectively, manufactured by BASF.

The Photoinitiator OXE-1 and the Photoinitiator OXE-2 are ketoxime ester photoinitiators. Their molecular structures are as follows:

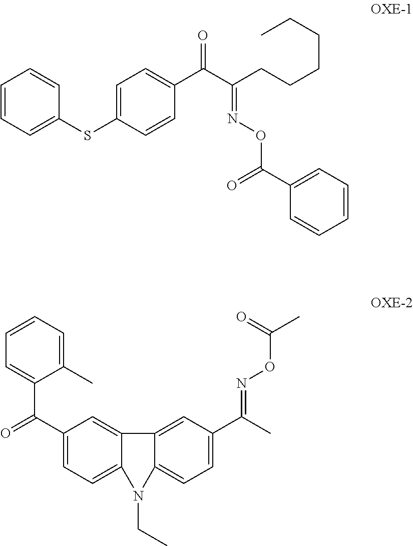 [SMILES: CCCCCC/C(=N\OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21]

Song Guoqiang, Hu Chunqing and Wang Bing, etc. disclose synthesis process of photoinitiator OXE-1 in detail in the organic synthesis materials part of the 17th National Symposium on Organic and Fine Chemical Intermediates of the Chinese National Chemical Industry Association of Fine Chemical. Song Guoqiang, Hu Chunqing, Wang Bing et al. disclose synthesis process of photoinitiator OXE-2 in “Fine Chemicals” (2009.26 (10): 961-964). In one embodiment, the photoinitiator may include IRGACURE® OXE 01 or IRGACURE® OXE 02 produced by BASF.

In one embodiment, the blue color-resist comprises the following components: the binder resin is an acrylic resin; the monomer is at least one selected from the group consisting of dipentaerythritol hexaacrylate, trimethylolpropane triacrylate, and pentaerythritol tripropylene; the photoinitiator is at least one selected from the group consisting of photoinitiator 369, photoinitiator 379, photoinitiator OXE-1, and photoinitiator OXE-2; and the solvent is at least one selected from the group consisting of 3-ethoxy propionic acid ethyl ester, propylene glycol methyl ether, propylene glycol methyl ether acetate, and N, N-methylene bisacrylamide.

In one embodiment, in order to facilitate molding of the blue color-resist and improve its overall properties, the monomer comprises at least two selected from the group consisting of dipentaerythritol hexaacrylate, trimethylolpropane triacrylate, and pentaerythritol triacrylate. The photoinitiator comprises at least two selected from the group consisting of photoinitiator 369, photoinitiator 379, photoinitiator OXE-1, and photoinitiator OXE-2; and the solvent comprises at least two selected from the group consisting of 3-ethoxypropionate, propylene glycol methyl ether, propylene glycol methyl ether acetate, and N, N-methylene bisacrylamide.

In order to meet specific requirements, optional additives such as pigment dispersants, dispersing resins, leveling agents, antioxidants, adhesion promoters, ultraviolet absorbers, agglomeration preventing agents, organic acid, organic amine compounds, curing agents, or the like can be added in the blue color-resist.

In one embodiment, in order to uniformly disperse the blue pigment and the green pigment in the solution, a certain amount of pigment dispersant may be added thereto, and the amount thereof is preferably 10 to 30 parts by mass per 100 parts by mass of the pigment mixture. The pigment dispersant may be any type of pigment dispersant such as a polyester, a polyamine, an acrylic or the like.

In one embodiment, in order to make the coating smooth, level, and without bubbles, a certain amount of leveling agent is added into the blue color-resist. The amount of the leveling agent is generally 0.005%-0.6% by mass of a total mass of the raw materials of the blue color-resist. The leveling agent can be a silicone-based leveling agent having silicone-oxygen bonds in the molecule or a fluorine-based leveling agent having a fluorocarbon chain in the molecule.

In one embodiment, in order to improve heat resistance and light resistance of the pigment, antioxidants such as phenol-based antioxidants, phosphorus-based antioxidants and sulfur-based antioxidants can be added thereto.

In one embodiment, a method of the blue color-resist is briefly described below: first, a pigment and a part of solvent are uniformly mixed by stiffing to a predetermined concentration, followed by pre-disperse, viscosity and particle size distribution inspection, disperse, once again viscosity and particle size distribution inspection, dilution stiffing, filtering and filling, and inspection to obtain a mixture A. When a dispersant or a dispersion resin is used, it is also added in this step.

Then, separately, a binder resin, a monomer, a photoinitiator and the remaining solvent are mixed and stirred uniformly, followed by filtering and filling, and inspection to obtain a mixture B.

Then, the mixture A and the mixture B are mixed and stirred uniformly, followed by viscosity and particle size distribution inspection, stiffing, filtering and filling, and shipping inspection to form a mixture of raw materials. The shipping inspection may include inspection of viscosity, filtration effect, color, film thickness, and film-forming ability.

In one embodiment, during preparation of a color film substrate, the above-mentioned mixture of raw materials is uniformly coated on a substrate using a coating apparatus, followed by removing the solvent in a vacuum, prebaking, exposing to light, developing, baking to form a pattern of blue pixels having a desired shape. That is, a blue color-resist is formed on the color film substrate.

Another embodiment of the present disclosure provides application of the above blue color-resist for anti-blue light performance. The blue color-resist according to one embodiment of the present disclosure has anti-blue light function, and can be used in various fields with an anti-blue light requirement. In one embodiment, the blue color-resist can be used in the field of liquid crystal display. Specifically, a color filter layer having anti-blue light function can be prepared by using the blue color-resist according to one embodiment. Furthermore, a color film substrate having anti-blue light function can be prepared by including the color filer layer, and a liquid crystal display having an anti-blue light function can be obtained by including the color film substrate. As such, consumers can experience normal viewing effect while their eyes are protected from damaging at the same time.

Another example of the present disclosure is a color film substrate comprising the blue color-resist of according to one embodiment of the present disclosure. The color film substrate is composed of a transparent substrate, and a black matrix and a color filter layer distributed on the transparent substrate. The color filter layer is composed of red color-resist, green color-resist, and blue color-resist. The red color-resist, the green color-resist, the blue color-resist are arranged alternatively to form a number of repeating array of color-resist units. The black matrix is used to separate the above color-resist units. The color film substrate can reduce the damage of the blue light to human eye by using the blue color-resist having anti-blue light function, thereby achieving the effect of anti-blue light.

Another example of the present disclosure is a colored liquid crystal display apparatus. The colored liquid crystal display apparatus includes the color film substrate according to one embodiment of the present disclosure. Likewise, due to the blue color-resist according to one embodiment of the present disclosure, the colored liquid crystal display apparatus also has an anti-blue light function, which reduces damage of the blue light to human eye as much as possible while maintaining the viewing effect.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Hereinafter, the present invention will be described in more detail with reference to Examples. However, the scope of the present invention is not limited to the following Examples.

### EXAMPLES

In the following examples, the processes which do not have specified conditions are carried out in accordance with conventional conditions or conditions recommended by the manufacturer. Raw materials which do not have specified manufacturers and specifications are available through the purchase of conventional products.

In the following examples, the alkali-soluble photosensitive acrylic resin is a polymethylmethacrylate resin VH5 manufactured by Mitsubishi Rayon Polymer Materials (Nantong) Co., Ltd. Photoinitiator 369 is IRGACURE® 369 from BASF. Photoinitiator OXE-1 is IRGACURE® OXE 01 from BASF.

### Example 1

The blue color-resist of Example 1 is prepared by raw materials having a mass ratio of the following: alkali-soluble photosensitive acrylic resin:monomer:photoinitiator:solvent:mixture of blue pigment and green pigment=7:6:0.4:80:6. The monomer is composed of dipentaerythritol hexaacrylate and pentaerythritol triacrylate having a mass ratio of 1:1. The photoinitiator is composed of Photoinitiator 369 and Photoinitiator OXE-1 having a mass ratio of 1:1. The solvent is composed of ethyl 3-ethoxypropionate and propylene glycol methyl ether acetate having a mass ratio of 1:1. The mixture of blue pigment and green pigment is composed of 90% by weight of blue pigment and 10% by weight of green pigment. The blue pigment is composed of Pigment Blue 15:6 and Pigment Purple 23 having a mass ratio of 9:1. The green pigment is C.I. Pigment Green 36.

### Example 2

The blue color-resist of Example 2 is prepared by similar raw materials and process as that in Example 1 except for composition of the mixture of blue pigment and green pigment. Specifically, the mixture of blue pigment and green pigment of Example 2 is composed of 80% by weight of blue pigment and 20% by weight of green pigment. The blue pigment is composed of Pigment Blue 15:6 and Pigment Purple 23 having a mass ratio of 9:1. The green pigment is C.I. Pigment Green 36.

### Example 3

The blue color-resist of Example 3 is prepared by similar raw materials and process as that in Example 1 except for composition of the mixture of blue pigment and green pigment. Specifically, the mixture of blue pigment and green pigment of Example 3 is composed of 70% by weight of blue pigment and 30% by weight of green pigment. The blue pigment is composed of Pigment Blue 15:6 and Pigment Purple 23 having a mass ratio of 9:1. The green pigment is C.I. Pigment Green 36.

### Example 4

The blue color-resist of Example 4 is prepared by similar raw materials and process as that in Example 1 except for composition of the mixture of blue pigment and green pigment. Specifically, the mixture of blue pigment and green pigment of Example 4 is composed of 60% by weight of blue pigment and 40% by weight of green pigment. The blue pigment is composed of pigment blue 15:6 and pigment purple 23 having a mass ratio of 9:1. The green pigment is C.I. Pigment Green 36.

### Example 5

The blue color-resist of Example 5 is prepared by similar raw materials and process as that in Example 1 except for composition of the mixture of blue pigment and green pigment. Specifically, the mixture of blue pigment and green pigment of Example 5 is composed of 50% by weight of blue pigment and 50% by weight of green pigment. The blue pigment is composed of Pigment Blue 15:6 and Pigment Purple 23 having a mass ratio of 9:1. The green pigment is C.I. Pigment Green 36.

### Comparative Example

The blue color-resist of Comparative Example is prepared by similar raw materials and process as that in Example 1 except that only blue pigment is used and there is no green pigment in the mixture of blue pigment and green pigment. The blue pigment is composed of Pigment Blue 15:6 and Pigment Purple 23 having a mass ratio of 9:1.

### Characterization of Blue Color-Resists

Anti-blue light efficiency of each blue color-resist provided in Examples 1 to 5 and Comparative Example is measured. After a light passes through each of the above blue color-resists, peak wavelength, chromaticity, and luminance of the transmitted blue light are measured. The anti-blue light efficiency is calculated based on the following principle: Blue light damage intensity (L_{B})=weighted integral area of the blue light having wavelengths within a range of 400 nm-760 nm. It is calculated by the following formula:

$${L}_{B} = {\sum }_{400}^{760} {L}_{λ} \cdot B ( λ ) \cdot Δ λ$$

λ is a light wavelength, B(λ) is blue light weighting hazard factor at a light wavelength of λ, and L_{λ} is light intensity at a light wavelength of λ.

Blue light damage density (Z_{B})=blue light damage intensity/luminance, wherein luminance is expressed in L with a unit of cd/m². The blue light damage density is calculated as follows:

$${Z}_{B} = ( {\sum }_{400}^{760} {L}_{λ} \cdot B ( λ ) \cdot Δ λ ) / L$$

Anti-blue efficiency is calculated as follows:

η_{B}=(Z_{B0}−Z_{B1})/Z_{B0}

Z_{B0} refers to blue light damage density of the transmitted blue light after passing through the blue color-resist of Comparative Example. Z_{B1} refers to blue light damage density of the transmitted blue light after passing through the blue color-resist of an Example.

The test results are shown in Table 1 below:

TABLE 1

| | Blue color-resist | | | | | |
|---|---|---|---|---|---|---|
| | Comparative | Example | Example | Example | Example | Example |
| Item | Example | 1 | 2 | 3 | 4 | 5 |
| blue pigment | 100% | 90% | 80% | 70% | 60% | 50% |
| percentage | | | | | | |
| (% by weight) | | | | | | |
| green pigment | 0% | 10% | 20% | 30% | 40% | 50% |
| percentage | | | | | | |
| (% by weight) | | | | | | |
| x | 0.139 | 0.137 | 0.136 | 0.136 | 0.138 | 0.143 |
| y | 0.089 | 0.104 | 0.123 | 0.146 | 0.175 | 0.211 |
| T | 9.6% | 10.4% | 11.5% | 13.1% | 15.1% | 17.9% |
| peak wavelength of the | 470 nm | 475 nm | 480 nm | 480 nm | 485 nm | 495 nm |
| transmitted blue light | | | | | | |
| Anti-blue light | 0% | 9.85% | 19.42% | 29.18% | 40.09% | 53.16% |
| efficiency (%) | | | | | | |

| | |
|---|---|
| Color gamut | NTSC 73.5% (1931) |

x and y refer to the red and green components respectively in the CIE 1931 color space chromaticity diagram, both of which are capable of characterizing the chromaticity of the transmitted blue light. T represents transmittance of the transmitted blue light, which can be used to characterize the luminance of the transmitted blue light.

As shown in Table 1, compared with the comparative example, x and y are increased in the Examples 1-5. x and y each increases gradually from Example 1 to Example 5. In a case where R and G (i.e., the color of the red and green passages) are constant, this means that, in the chromaticity, a triangle of the color gamut is gradually smaller. That the triangle of the color gamut is gradually smaller means that the color gamut becomes smaller and the color expression becomes smaller. As B_{xy} (color chroma of blue channel) becomes larger, in order to maintain the same color gamut, R_{xy} and G_{xy} need to be adjusted. Therefore, in the comparative example and Examples 1-5, the blue color-resist is adjusted with the same color gamut reference (i.e., NTSC 73.5% (1931)). Accordingly, although a green pigment is added in the blue color-resist, loss of color gamut is compensated.

As shown in Table 1, by adding a certain percentage of green pigment to the blue color-resist, the peak wavelength of the transmitted blue light after passing through the blue color-resist is shifted in the direction of the infrared area, and the peak wavelength increases gradually from 470 nm to 495 nm as the percentage of the green pigment gradually increases, thereby achieving an obvious anti-blue light effect. Furthermore, the chromaticity of the blue color-resist is still within an acceptable range of the user.

FIG. 1 shows wavelength distribution of transmitted blue lights after passing through blue color-resists having different ratios of a blue pigment to a green pigment according to some embodiments. As shown in FIG. 1, the peak wavelength of the transmitted blue light increases gradually from 470 nm to 495 nm as the percentage of the green pigment gradually increases in the blue color-resist.

FIG. 2 shows a weighted damage of a blue light (a) before passing through a blue color-resist and (b) after passing through a blue color-resist, according to one embodiment. The blue color-resist is obtained in Example 2 and contains a mixture of blue pigment and green pigment at a mass ratio of 8:2. As shown in FIG. 2, the weighted damage of the blue light decreases significantly after passing through the blue color-resist comparing to that before passing through the blue color-resist.

1. A blue color-resist comprising a blue pigment and a green pigment.

2. The blue color-resist of claim 1, wherein a mass ratio of the blue pigment to the green pigment is approximately in a range of 1:1 to 50:1.

3. The blue color-resist of claim 2, wherein the mass ratio of the blue pigment to the green pigment is approximately in a range of 1:1 to 9:1.

4. The blue color-resist of claim 1, wherein the blue color-resist is configured to have an anti-blue light efficiency of about 9% or more.

5. The blue color-resist of claim 1, wherein the blue color-resist is configured to have an anti-blue light efficiency of about 20% or more.

6. The blue color-resist of claim 1, wherein a wavelength of a blue light after being transmitted through the blue color-resist is shifted toward infrared region.

7. The blue color-resist of claim 1, wherein a peak wavelength of a blue light after being transmitted through the blue color-resist is red-shifted to a range of 475 nm to 495 nm.

8. The blue color-resist of claim 1, wherein the blue pigment comprises at least one selected from the group consisting of Pigment Blue 15:6, Pigment Blue 15:4, and Pigment Blue 15:3; and the green pigment comprises at least one selected from the group consisting of Pigment Green 58, Pigment Green 7, Pigment Green 36, and Pigment Green 59.

9. The blue color-resist of claim 1, wherein the blue pigment further comprises pigment violet 23.

10. The blue color-resist of claim 1, wherein starting raw materials for preparing the blue color-resist comprise a) a binder resin, b) a monomer, c) a photoinitiator, d) a solvent, and e) a mixture of the blue pigment and the green pigment.

11. The blue color-resist of claim 10, wherein a mass ratio of the binder resin:the monomer:the photoinitiator:the solvent:the mixture of the blue pigment and the green pigment is in a range of 5-8:5-8:0.2-0.6:75-85:5-8, respectively.

12. The blue color-resist of claim 10, wherein the binder resin comprises an acrylic resin.

13. The blue color-resist of claim 10, wherein the monomer comprises at least one selected from the group consisting of dipentaerythritol hexaacrylate, trimethylolpropane triacrylate, and pentaerythritol triacrylate.

14. The blue color-resist of claim 10, wherein the photoinitiator comprises at least one selected from the group consisting of Photoinitiator 369, Photoinitiator 379, Photoinitiator OXE-1, and Photoinitiator OXE-2.

15. The blue color-resist of claim 10, wherein the solvent comprises at least one selected from the group consisting of ethyl 3-ethoxypropionate, propylene glycol methyl ether, propylene glycol methyl ether acetate, and N, N-methylenebisacrylamide.

16. A color film substrate comprising the blue color-resist according to claim 1.

17. A liquid crystal display apparatus comprising the color film substrate according to claim 16.
